(19) United States
(12) Patent Application Publication
(10) Pub. No.: US 2021/0175178 A1
(43) Pub. Date: Jun. 10, 2021

(54) PACKAGE COMPRISING A DOUBLE-SIDED REDISTRIBUTION PORTION

(71) Applicant: QUALCOMM Incorporated, San Diego, CA (US)

(72) Inventors: Hong Bok WE, San Diego, CA (US); Aniket PATIL, San Diego, CA (US); Kuiwon KANG, San Diego, CA (US); Zhijie WANG, San Diego, CA (US)

(21) Appl. No.: 16/704,378

(22) Filed: Dec. 5, 2019

(51) Int. Cl. H01L 23/538; H01L 23/31; H01L 23/00; H01L 21/683; H01L 21/48; H01L 21/56

(52) U.S. Cl. CPC H01L 23/5389; H01L 2221/68372; H01L 23/5383; H01L 23/5386; H01L 24/20; H01L 24/19; H01L 21/6835; H01L 21/4853; H01L 21/4857; H01L 21/568; H01L 21/565; H01L 2224/214; H01L 2924/19041; H01L 2924/19105; H01L 23/3128

(57) ABSTRACT

A package comprising a first integrated device, a first encapsulation layer, a redistribution portion, a second integrated device and an encapsulation layer. The first encapsulation layer encapsulates the first integrated device. The redistribution portion includes a plurality of redistribution interconnects. The redistribution portion includes a first surface and a second surface. The first integrated device and the first encapsulation layer are coupled to the first surface of the redistribution portion. The second integrated device is coupled to the second surface of the redistribution portion. The second encapsulation layer is coupled to the second surface of the redistribution portion such that the second encapsulation layer encapsulates the second integrated device.

### FIELD

Various features relate to packages that include an integrated device, but more specifically to a package that includes a double-sided redistribution portion.

### BACKGROUND

FIG. 1 illustrates a package 100 that includes a substrate 102, an integrated device 104, and an encapsulation layer 108. The substrate 102 includes a plurality of dielectric layers 120, a plurality of interconnects 122, and a plurality of solder interconnects 124. A plurality of solder interconnects 144 are coupled to the substrate 102 and the integrated device 104. The encapsulation layer 108 encapsulates the integrated device 104 and the plurality of solder interconnects 144. A package that includes the substrate 102 may be limited by how compact and thin it can be. There is an ongoing need to provide more compact and thin packages.

### SUMMARY

Various features relate to packages that include an integrated device, but more specifically to a package that includes a double sided redistribution layer (RDL) portion.

One example provides a package comprising a first integrated device, a first encapsulation layer, a redistribution portion, a second integrated device and an encapsulation layer. The first encapsulation layer encapsulates the first integrated device. The redistribution portion includes a plurality of redistribution interconnects. The redistribution portion includes a first surface and a second surface. The first integrated device and the first encapsulation layer are coupled to the first surface of the redistribution portion. The second integrated device is coupled to the second surface of the redistribution portion. The second encapsulation layer is coupled to the second surface of the redistribution portion such that the second encapsulation layer encapsulates the second integrated device.

Another example provides an apparatus that that includes a first integrated device, a first means for encapsulation configured for encapsulating the first integrated device, a redistribution portion, a second integrated device and a second means for encapsulation. The redistribution portion includes a plurality of redistribution interconnects. The redistribution portion includes a first surface and a second surface. The first integrated device and the first means for encapsulation are coupled to the first surface of the redistribution portion. The second integrated device is coupled to the second surface of the redistribution portion. The second means for encapsulation is coupled to the second surface of the redistribution portion. The second means for encapsulation is configured for encapsulating the second integrated device.

Another example provides a method for fabricating a package. The method provides a first integrated device. The method forms a first encapsulation layer over the first integrated device. The method forms a redistribution portion over the first integrated device and the first encapsulation layer. The method of forming the redistribution portion includes forming a plurality of redistribution interconnects. The method couples a second integrated device to a second surface of the redistribution portion. The method forms a second encapsulation layer over the second surface of the redistribution portion such that the second encapsulation layer encapsulates the second integrated device.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a profile view of a package that includes an integrated device and a substrate.

FIG. 2 illustrates a profile view of a package that includes a double-sided redistribution portion.

FIG. 3 illustrates a profile view of a package that includes a double-sided redistribution portion.

FIG. 4 illustrates a profile view of a package that includes a double-sided redistribution portion.

FIGS. 5A-5F illustrate an exemplary sequence for fabricating a package that includes a double-sided redistribution portion.

FIGS. 6A-6C illustrate an exemplary sequence for fabricating a package that includes a double-sided redistribution portion.

FIGS. 7A-7C illustrate an exemplary sequence for fabricating a package that includes a double-sided redistribution portion.

FIG. 8 illustrates an exemplary flow diagram of a method for fabricating a package that includes a double-sided redistribution portion.

FIG. 9 illustrates various electronic devices that may integrate a die, an integrated device, an integrated passive device (IPD), a passive component, a package, and/or a device package described herein.

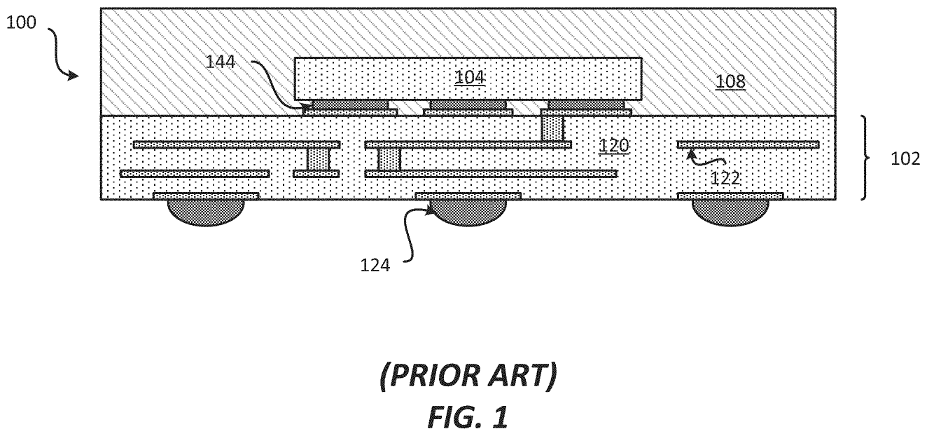

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package that includes a first integrated device, a first encapsulation layer, a redistribution portion, a second integrated device and an encapsulation layer. The first encapsulation layer encapsulates the first integrated device. The redistribution portion includes a plurality of redistribution interconnects. The redistribution portion includes a first surface and a second surface. The first integrated device and the first encapsulation layer are coupled to the first surface of the redistribution portion. The second integrated device is coupled to the second surface of the redistribution portion. The second encapsulation layer is coupled to the second surface of the redistribution portion such that the second encapsulation layer encapsulates the second integrated device. The redistribution portion has a thickness that is thinner than package substrates, which allows the package to be thinner and have a more compact form factor.

### Exemplary Package Comprising a Double-Sided Redistribution Portion

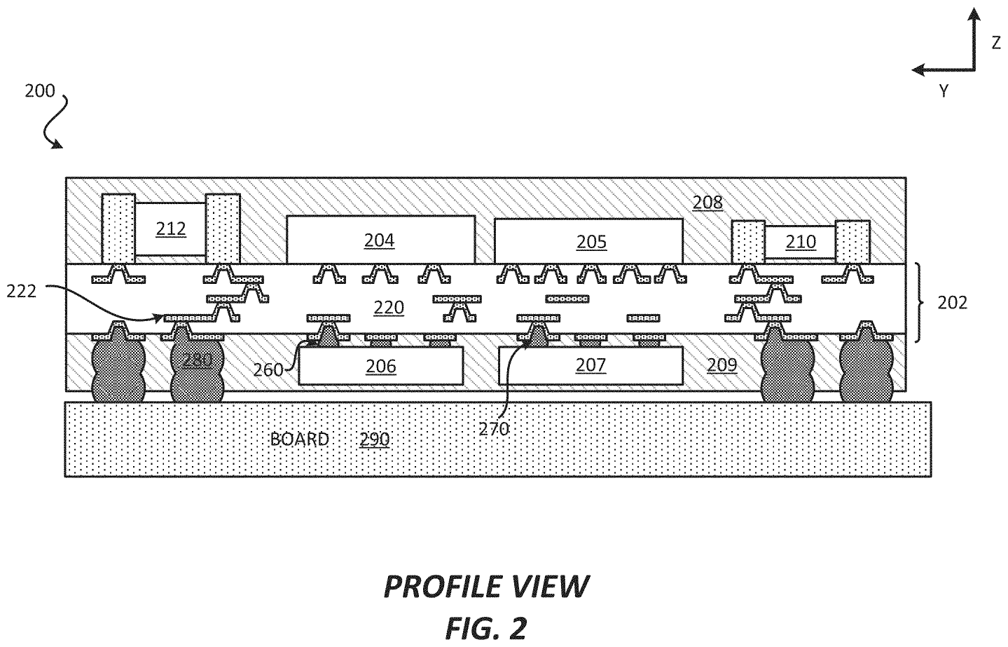

FIG. 2 illustrates a profile view of a package 200 that includes a double-sided redistribution portion. The package 200 is coupled to a board 290 (e.g., printed circuit board (PCB)) through a plurality of solder interconnects 280. The package 200 provides a package with a compact small factor.

As shown in FIG. 2, the package 200 includes a redistribution portion 202, an integrated device 204, an integrated device 205, an integrated device 206, an integrated device 207, an encapsulation layer 208, an encapsulation layer 209, a passive device 210 and a passive device 212.

The redistribution portion 202 may include a double-sided redistribution portion, where integrated device(s) may be coupled to both surfaces (e.g., top surface, bottom surface) of the redistribution portion 202. The redistribution portion 202 includes a first surface (e.g., top surface) and a second surface (e.g., bottom surface). The redistribution portion 202 includes at least one dielectric layer 220 and a plurality of redistribution interconnects 222. The plurality of redistribution interconnects 222 may include a U-shape interconnect and/or V-shape interconnect. The terms “U-shape” and “V-shape” shall be interchangeable. The at least one dielectric layer 220 may include a polymer. The plurality of redistribution interconnects 222 may have a minimum pitch and a minimum line and spacing (L/S). In some implementations, the minimum pitch for the plurality of redistribution interconnects 222 is in a range of approximately 100-200 micrometers (μm). In some implementations, the minimum line and spacing (L/S) for the plurality of redistribution interconnects 222 is in a range of approximately 5/5-20/20 micrometers (μm). The redistribution portion 202 may be thinner than other substrates that have the same number of metal layers. The thinner redistribution portion 202 allows the package 200 to be thinner and more compact than other packages that include substrates formed using non-redistribution layers fabrication processes. As an example, when a redistribution layer (RDL) fabrication process is used to fabricate the redistribution portion (e.g., 202), the thickness of each of the redistribution metal layers (on which redistribution interconnects 222 are formed) may be approximately 5-10 micrometers (μm). In contrast, interconnects for substrates that are fabricated using Semi-Additive Processing (SAP) or modified Semi Additive Processing (mSAP) for example, have a thickness that is approximately 15 micrometers (μm). The dielectric layer 220 may be considered as one dielectric layer 220. However, in some implementations, the process of forming the dielectric layer 220 may include forming several dielectric layers over one another. In some implementations, when a redistribution layer (RDL) fabrication process is used, each dielectric layer may have a thickness that is approximately 5-10 micrometers (μm). In contrast, when SAP or mSAP is used to form the dielectric layers of a substrate, each dielectric layer of the substrate is approximately 20-25 micrometers (μm).

The integrated device 204 is coupled to a first surface (e.g., top surface) of the redistribution portion 202. In particular, the integrated device 204 may be directly coupled to one or more redistribution interconnects from the plurality of redistribution interconnects 222, such that a coupling between the integrated device 204 and the redistribution interconnect is free of solder interconnect. The integrated device 205 is coupled to the first surface of the redistribution portion 202. In particular, the integrated device 205 may be directly coupled to one or more redistribution interconnects from the plurality of redistribution interconnects 222, such that a coupling between the integrated device 205 and the redistribution interconnect is free of solder interconnect. The integrated device 204 and the integrated device 205 may be co-planar to each other.

The passive device 210 is coupled to the first surface of the redistribution portion 202. In particular, the passive device 210 may be directly coupled to one or more redistribution interconnects from the plurality of redistribution interconnects 222, such that a coupling between the passive device 210 and the redistribution interconnect is free of solder interconnect. The passive device 212 is coupled to the first surface of the redistribution portion 202. In particular, the passive device 212 may be directly coupled to one or more redistribution interconnects from the plurality of redistribution interconnects 222, such that a coupling between the passive device 212 and the redistribution interconnect is free of solder interconnect. A passive device (e.g., 210, 212) may include a capacitor.

The encapsulation layer 208 may be coupled to the first surface of the redistribution portion 202 such that the encapsulation layer 208 at least partially encapsulates the integrated device 204, the integrated device 205, the passive device 210 and/or the passive device 212. The encapsulation layer 208 may be a first encapsulation layer. The encapsulation layer 208 may be a means for encapsulation. The encapsulation layer 208 may include a mold, a resin, an epoxy and/or polymer.

The integrated device 206 is coupled to a second surface (e.g., bottom surface) of the redistribution portion 202. The integrated device 206 is coupled to the redistribution portion 202 through a plurality of solder interconnects 260. In particular, the integrated device 206 is coupled to one or more redistribution interconnects from the plurality of redistribution interconnects 222, through the plurality of solder interconnects 260. The plurality of solder interconnects 260 may include copper pillars and/or solder interconnects. The integrated device 207 is coupled to the second surface of the redistribution portion 202. The integrated device 207 is coupled to the redistribution portion 202 through a plurality of solder interconnects 270. In particular, the integrated device 207 is coupled to one or more redistribution interconnects from the plurality of redistribution interconnects 222, through the plurality of solder interconnects 270. The plurality of solder interconnects 270 may include copper pillars and/or solder interconnects. The integrated devices 204, 205, 206 and 206 may share the same redistribution portion 202.

A plurality of solder interconnects 280 is coupled to the second surface of the redistribution portion 202. In particular, the plurality of solder interconnects 280 is coupled to redistribution interconnects from the plurality of redistribution interconnects 222.

The encapsulation layer 209 may be coupled to the second surface of the redistribution portion 202 such that the encapsulation layer 209 at least partially encapsulates the integrated device 206, the integrated device 207 and/or the plurality of solder interconnects 280. The size and/or shape of the plurality of solder interconnects 280 may vary with different implementations. The encapsulation layer 209 may be a second encapsulation layer. The encapsulation layer 209 may be a means for encapsulation. The encapsulation layer 209 may include a mold, a resin, an epoxy and/or polymer. The encapsulation layer 209 may be similar to the encapsulation layer 208. In some implementations, a surface (e.g., bottom surface) of the encapsulation layer 209 may be co-planar with a back side surface of the integrated device 206 and/or a back side surface of the integrated device 207.

The integrated device (e.g., 204, 205, 206, 207) may include a die (e.g., bare die). The integrated device may include a radio frequency (RF) device, a passive device, a filter, a capacitor, an inductor, an antenna, a transmitter, a receiver, a GaAs based integrated device, a surface acoustic wave (SAW) filters, a bulk acoustic wave (BAW) filter, a light emitting diode (LED) integrated device, a silicon carbide (SiC) based integrated device, and/or combinations thereof.

Different implementations may couple different components and/or different numbers of components to the redistribution portion 202. Different implementations may use different interconnects to couple the package to a board 290.

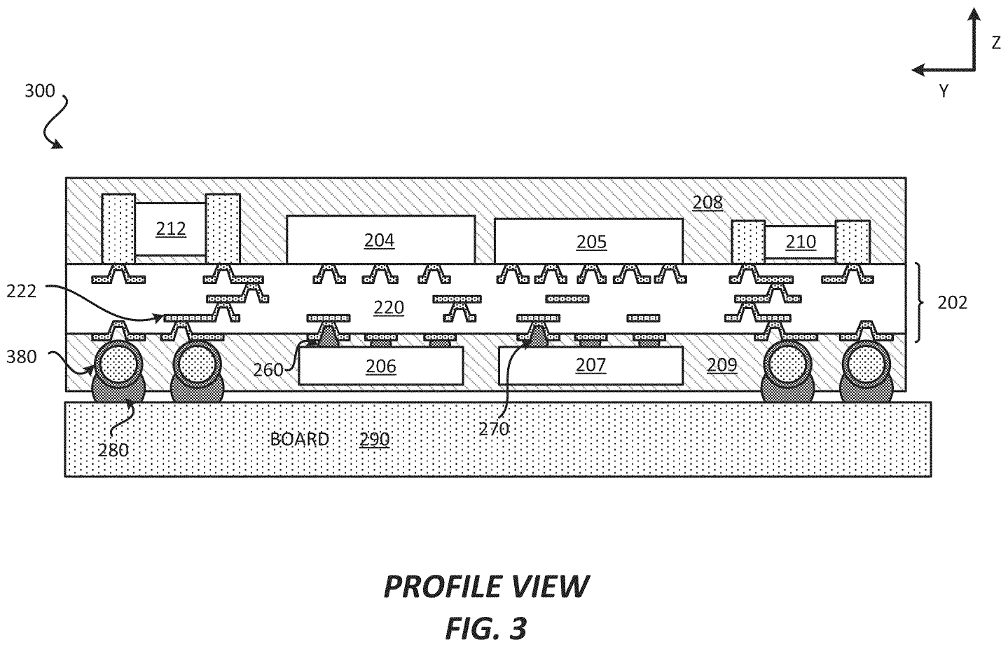

FIG. 3 illustrates a profile view of a package 300 that includes a double-sided redistribution portion. The package 300 is coupled to a board 290 (e.g., printed circuit board (PCB)) through a plurality of ball interconnects 380 and a plurality of solder interconnects 280. The package 300 is similar to the package 200 of FIG. 2, and thus includes similar components as the package 200.

The package 300 includes the redistribution portion 202, the integrated device 204, the integrated device 205, the integrated device 206, the integrated device 207, the encapsulation layer 208, the encapsulation layer 209, the passive device 210 and the passive device 212, as described above.

As shown in FIG. 3, the package 300 includes the plurality of ball interconnects 380. The plurality of ball interconnects 380 may include copper balls, which may be circular interconnects with solder. The plurality of ball interconnects 380 is coupled to the second surface of the redistribution portion 202. In particular, the plurality of ball interconnects 380 is coupled to redistribution interconnects from the plurality of redistribution interconnects 222. The encapsulation layer 209 encapsulates the plurality of ball interconnects 380. The plurality of ball interconnects 380 may be co-planar with the integrated device 206 and/or the integrated device 207. The plurality of solder interconnects 280 is coupled to the plurality of ball interconnects 380.

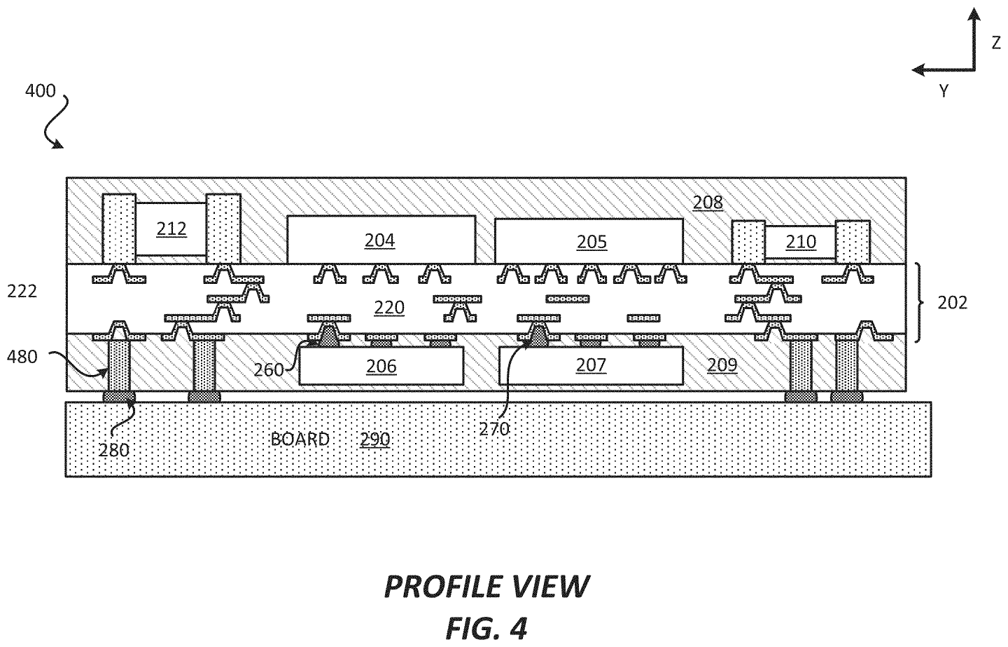

FIG. 4 illustrates a profile view of a package 400 that includes a double-sided redistribution portion. The package 400 is coupled to a board 290 (e.g., printed circuit board (PCB)) through a plurality of pillar interconnects 480 and a plurality of solder interconnects 280. The package 400 is similar to the package 200 of FIG. 2, and thus includes similar components as the package 200.

The package 400 includes the redistribution portion 202, the integrated device 204, the integrated device 205, the integrated device 206, the integrated device 207, the encapsulation layer 208, the encapsulation layer 209, the passive device 210 and the passive device 212, as described above.

As shown in FIG. 4, the package 400 includes the plurality of pillar interconnects 480. The plurality of pillar interconnects 480. The plurality of pillar interconnects 480 is coupled to the second surface of the redistribution portion 202. In particular, the plurality of pillar interconnects 480 is coupled to redistribution interconnects from the plurality of redistribution interconnects 222. The encapsulation layer 209 encapsulates the plurality of pillar interconnects 480. The plurality of pillar interconnects 480 may be co-planar with the integrated device 206 and/or the integrated device 207. The plurality of solder interconnects 280 is coupled to the plurality of pillar interconnects 480. The plurality of pillar interconnects 480 may be considered as through mold vias (TMVs).

Having described various packages with a double-sided redistribution portion, processes for fabricating a package that includes a double-sided redistribution portion will now be described below.

### Exemplary Sequence for Fabricating a Package Comprising a Double-Sided Redistribution Portion

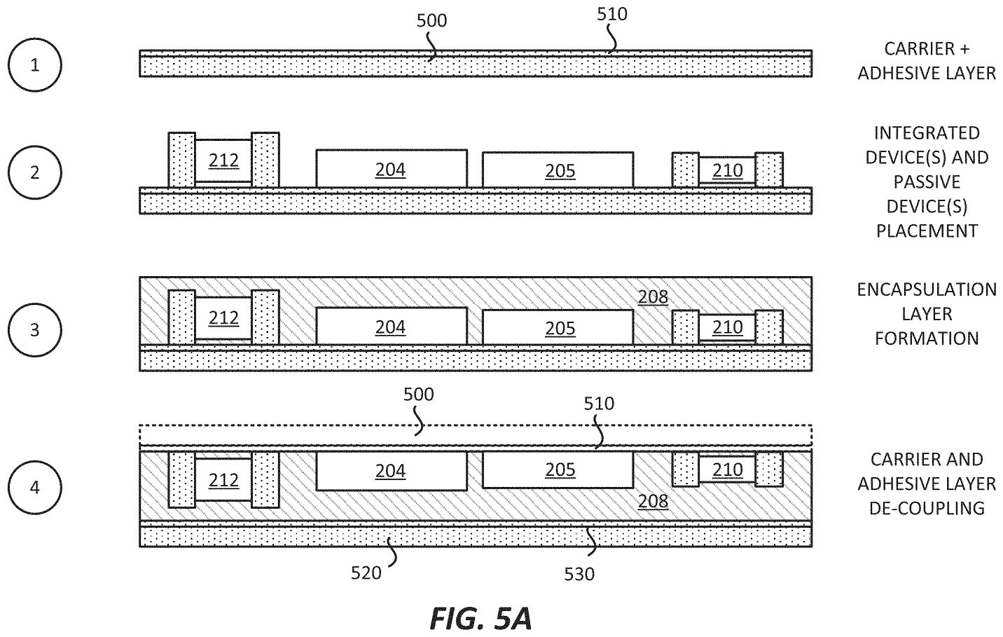

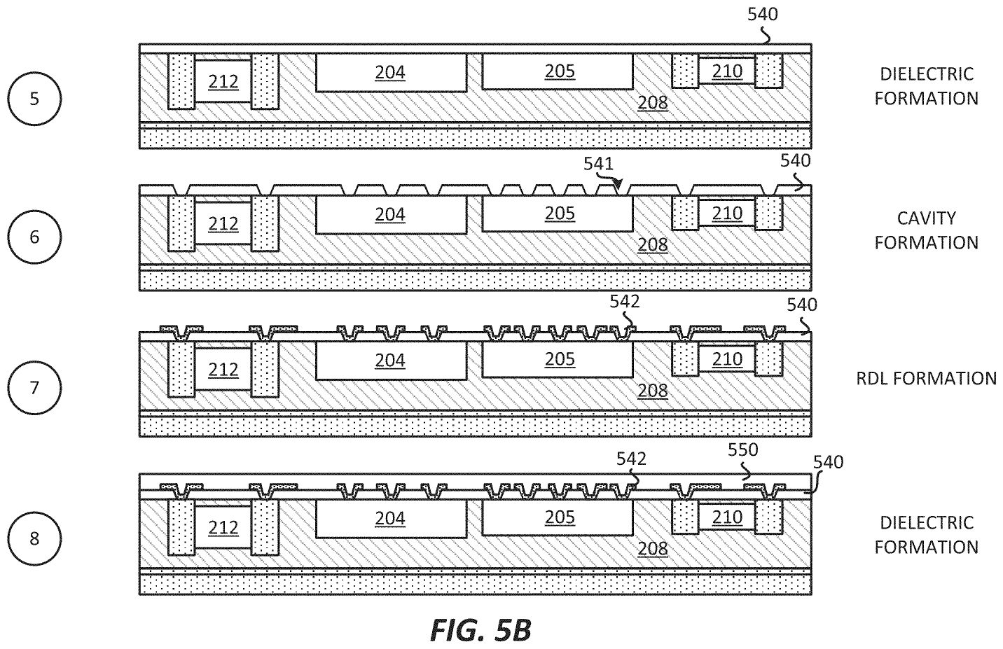

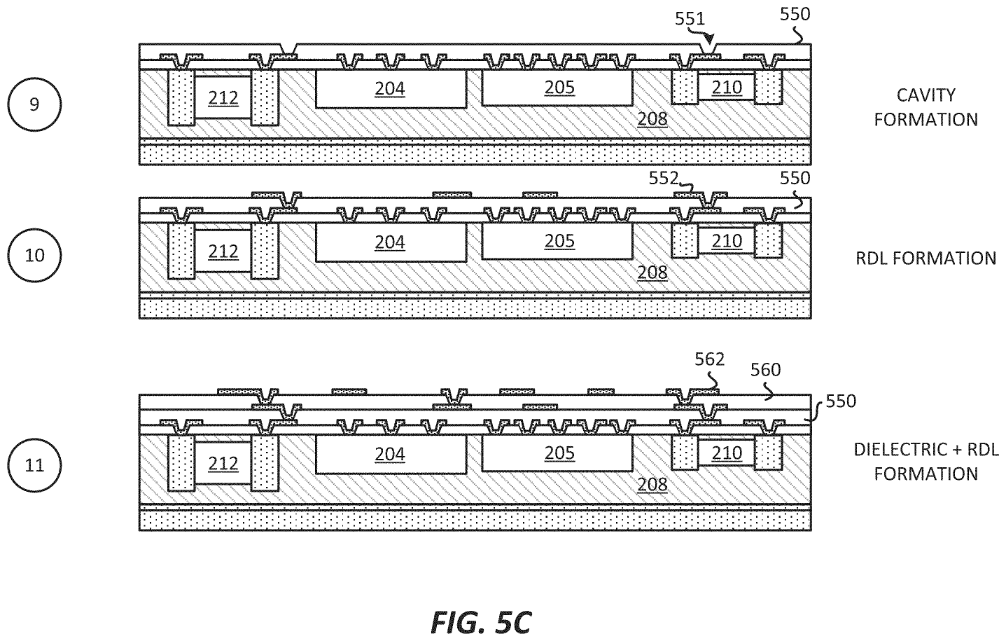

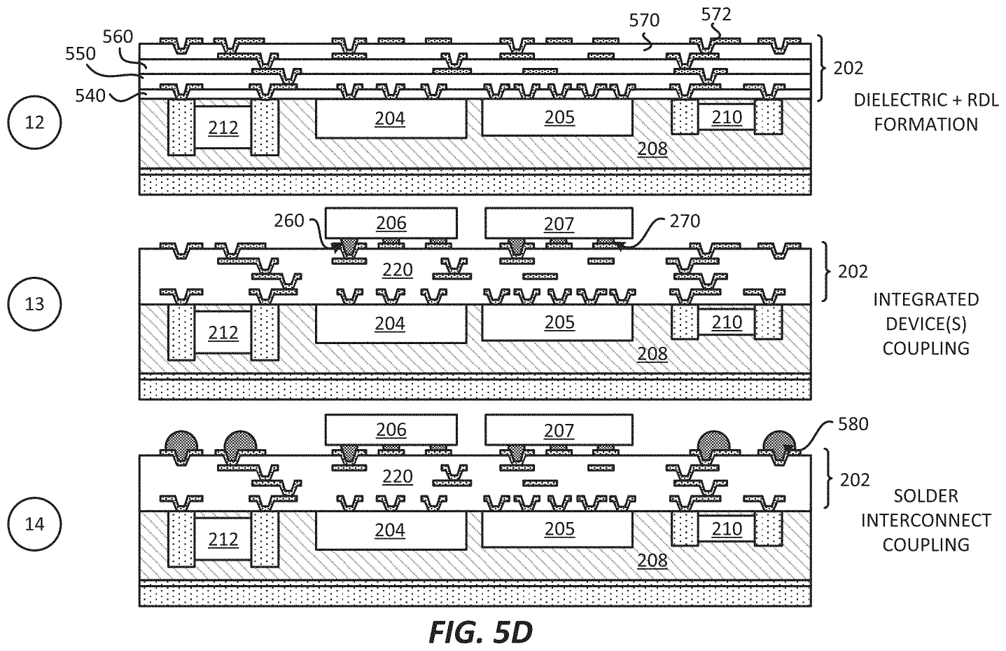

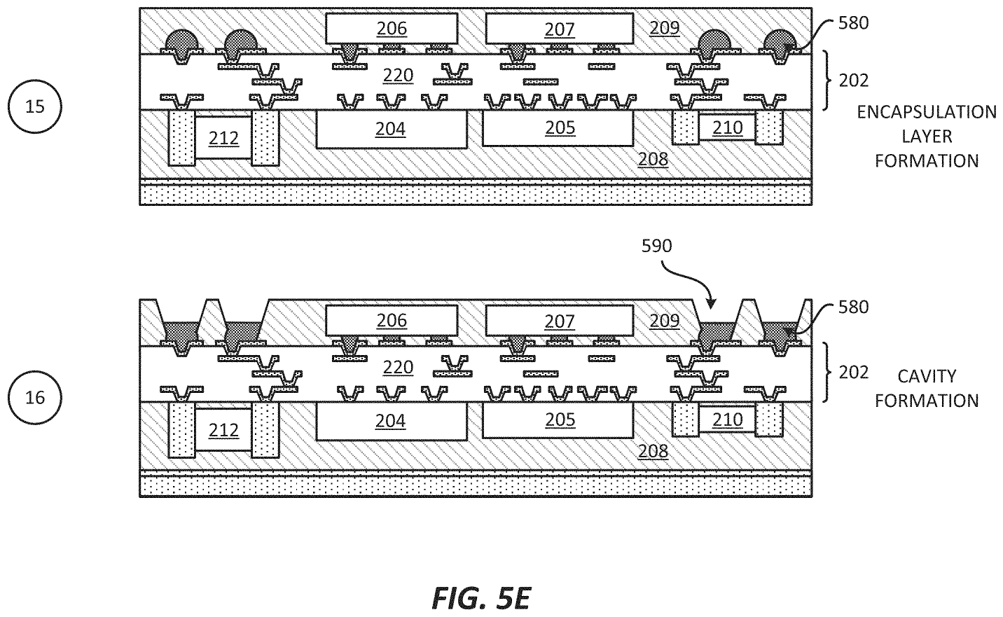

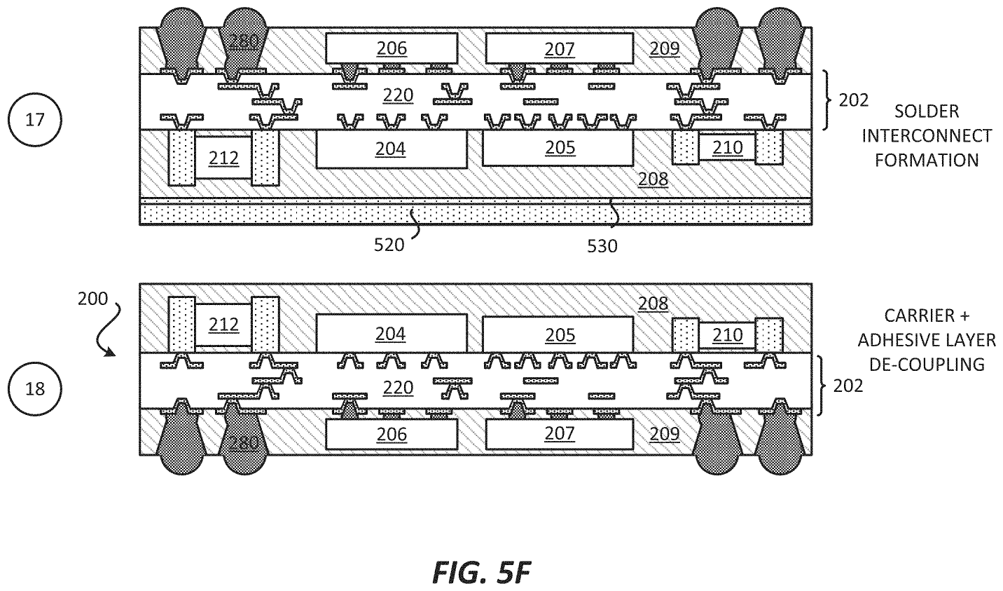

FIGS. 5A-5F illustrate an exemplary sequence for providing or fabricating a package that includes a double-sided redistribution portion. In some implementations, the sequence of FIGS. 5A-5F may be used to provide or fabricate the package 200 of FIG. 2, or any of the packages described in the disclosure.

It should be noted that the sequence of FIGS. 5A-5F may combine one or more stages in order to simplify and/or clarify the sequence for providing or fabricating the package. In some implementations, the order of the processes may be changed or modified. In some implementations, one or more of processes may be replaced or substituted without departing from the spirit of the disclosure. Different implementations may fabricate an package differently.

Stage 1, as shown in FIG. 5A, illustrates a state after a carrier 500 and an adhesive layer 510 are provided. The carrier 500 may be a substrate and/or a wafer. The carrier 500 may include glass and/or silicon. The carrier 500 may be a first carrier. The adhesive layer 510 may be disposed (e.g., formed) over the carrier 500. The adhesive layer 510 may be an adhesive film.

Stage 2 illustrates a state after the integrated device 204, the integrated device 205, the passive device 210 and the passive device 212 are placed over the adhesive layer 510 and the carrier 500. A pick and place method may be used to place the integrated device 204, the integrated device 205, the passive device 210 and the passive device 212. Different implementations may place different devices and/or different number of devices over the adhesive layer 510 and the carrier 500.

Stage 3 illustrates a state after the first encapsulation layer 208 is formed over the adhesive layer 510 and the carrier 500, such that the first encapsulation layer 208 at least partially encapsulates the integrated device 204, the integrated device 205, the passive device 210 and the passive device 212. The process of forming and/or disposing the first encapsulation layer 208 may include using a compression and transfer molding process, a sheet molding process, or a liquid molding process.

Stage 4 illustrates a state after another carrier 520 and another adhesive layer 530 are provided over the first encapsulation layer 208. The carrier 520 may be a substrate and/or a wafer. The carrier 520 may include glass and/or silicon. The carrier 520 may be a second carrier. The adhesive layer 530 may be disposed (e.g., formed) over the carrier 520. The adhesive layer 530 may be an adhesive film. Stage 4 also illustrates a state after the adhesive layer 510 and the carrier 500 are decoupled from the first encapsulation layer 208 and the integrated device 204, the integrated device 205, the passive device 210 and the passive device 212.

Stage 5, as shown in FIG. 5B, a state after a dielectric layer 540 is formed (e.g., disposed) over the first encapsulation layer 208 and the integrated device 204, the integrated device 205, the passive device 210 and the passive device 212. The dielectric layer 540 may include a polymer material. However, different implementations may include different materials. The dielectric layer 540 may be a passivation layer. Different implementations may use different types of passivation layers. The passivation layer may include PSR, SR, PID and/or ABF.

Stage 6 illustrates a state after cavities 541 are formed in the dielectric layer 540. An etching process (e.g., photo etching process) may be used to form the cavities 541. A photo etching process may be used when the dielectric layer 540 includes a photo imageable dielectric layer.

Stage 7 illustrates a state after a plurality of redistribution interconnects 542 is formed over the dielectric layer 540 and the cavities 541. Forming the plurality of redistribution interconnects 542 may include forming a seed layer, performing a lithography process, a plating process, a stripping process and/or an etching process. Stage 7 illustrates an example of forming a redistribution layer (e.g., redistribution metal layer) for the redistribution portion 202. The plurality of redistribution interconnects 542 may be part of the plurality of redistribution interconnects 222.

Stage 8 illustrates a state after the dielectric layer 550 is formed over the plurality of redistribution interconnects 542 and the dielectric layer 540. The dielectric layer 550 may include polymer. The dielectric layer 550 may be similar to the dielectric layer 540.

Stage 9, as shown in FIG. 5C, illustrates a state after cavities 551 are formed in the dielectric layer 550. An etching process (e.g., photo etching process) may be used to form the cavities 551.

Stage 10 illustrates a state after a plurality of redistribution interconnects 552 is formed over the dielectric layer 550 and the cavities 551. Forming the plurality of redistribution interconnects 552 may include forming a seed layer, performing a lithography process, a plating process, a stripping process and/or an etching process. Stage 10 illustrates an example of forming a redistribution layer (e.g., redistribution metal layer) for the redistribution portion 202. The plurality of redistribution interconnects 552 may be part of the plurality of redistribution interconnects 222.

Stage 11 illustrates a state after the dielectric layer 560 and a plurality of redistribution interconnects 562 are formed over the dielectric layer 550 and the plurality of redistribution interconnects 552. The dielectric layer 560 may include polymer. The dielectric layer 560 may be similar to the dielectric layer 550. Forming the dielectric layer 560 may include forming cavities in the dielectric layer 560, as described at Stages 6 and 9. An etching process (e.g., photo etching process) may be used to form the cavities in the dielectric layer 560. Forming the plurality of redistribution interconnects 562 may include forming a seed layer, performing a lithography process, a plating process, a stripping process and/or an etching process. Stage 11 illustrates an example of forming a redistribution layer (e.g., redistribution metal layer) for the redistribution portion 202. The plurality of redistribution interconnects 562 may be part of the plurality of redistribution interconnects 222.

Stage 12, as shown in FIG. 5D, illustrates a state after the dielectric layer 570 and a plurality of redistribution interconnects 572 are formed over the dielectric layer 560 and the plurality of redistribution interconnects 562. The dielectric layer 570 may include polymer. The dielectric layer 570 may be similar to the dielectric layer 560. Forming the dielectric layer 570 may include forming cavities in the dielectric layer 570, as described at Stages 6 and 9. An etching process (e.g., photo etching process) may be used to form the cavities in the dielectric layer 570. Forming the plurality of redistribution interconnects 572 may include forming a seed layer, performing a lithography process, a plating process, a stripping process and/or an etching process. Stage 12 illustrates an example of forming a redistribution layer (e.g., redistribution metal layer) for the redistribution portion 202. The plurality of redistribution interconnects 572 may be part of the plurality of redistribution interconnects 222. The plurality of redistribution interconnects (e.g., 542, 552, 562, 572) may include a U-shape interconnect and/or V-shape interconnect. The terms “U-shape” and “V-shape” shall be interchangeable. The terms “U-shape” and “V-shape” may refer to the side profile shape of the interconnects and/or redistribution interconnects. The U-shape interconnect and the V-shape interconnect may have a top portion and a bottom portion.

Stage 12 may illustrate the redistribution portion 202 that includes the at least one dielectric layer 220 and the plurality of redistribution interconnects 222. The dielectric layers 540, 550, 560 and 570 may be represented by the at least one dielectric layer 220. Stage 12 illustrates that the integrated device 204, the integrated device 205, the passive device 210 and the passive device 212 are coupled to a first surface of the redistribution portion 202. When the redistribution layer (RDL) fabrication process is used to fabricate the redistribution portion (e.g., 202), the thickness of each of the dielectric layers (e.g., 540, 550, 560, 570) may be approximately 5-10 micrometers (μm), and the thickness of each of the redistribution metal layers (on which redistribution interconnects are formed) may be approximately 5-10 micrometers (μm).

Stage 13 illustrates a state after the integrated device 206 and the integrated device 207 are coupled to a second surface of the redistribution portion 202. In particular, the integrated device 206 is coupled to redistribution interconnects 222 of the redistribution portion 202, through the plurality of solder interconnects 260. The integrated device 206 is coupled to redistribution interconnects 222 of the redistribution portion 202, through the plurality of solder interconnects 260. The integrated device 207 is coupled to redistribution interconnects 222 of the redistribution portion 202, through the plurality of solder interconnects 270.

Stage 14 illustrates a state after the plurality of solder interconnects 580 is coupled to the second surface of the redistribution portion 202. In particular the plurality of solder interconnects 580 is coupled to the redistribution interconnects 222.

Stage 15, as shown in FIG. 5E, illustrates a state after the second encapsulation layer 209 is formed over the second surface of the redistribution portion 202, such that the second encapsulation layer 209 at least partially encapsulates the integrated device 206, the integrated device 207, and/or the plurality of solder interconnects 580. The process of forming and/or disposing the second encapsulation layer 209 may include using a compression and transfer molding process, a sheet molding process, or a liquid molding process.

Stage 16 illustrates a state after cavities 590 are formed in the second encapsulation layer 209. A laser process or etching process may be used to form the cavities 590. The cavities 590 may be formed to expose the plurality of solder interconnects 580. The shape and/or size of the cavities 590 may vary with different implementations.

Stage 17, as shown in FIG. 5F, illustrates a state after the plurality of solder interconnects 280 is provided over the cavities 590 such that the plurality of solder interconnects 280 is coupled to the plurality of solder interconnects 580. The plurality of solder interconnects 280 may include the plurality of solder interconnects 580.

Stage 18 illustrates a state after the adhesive layer 530 and the carrier 520 are decoupled from the first encapsulation layer 208. Stage 18 may include the package 200 that includes the redistribution portion 202, as described in FIG. 2. Stage 18 may illustrate a state after the package 200 has been flipped after the adhesive layer 530 and the carrier 520 are decoupled from the first encapsulation layer 208.

### Exemplary Sequence for Fabricating a Package Comprising a Double-Sided Redistribution Portion

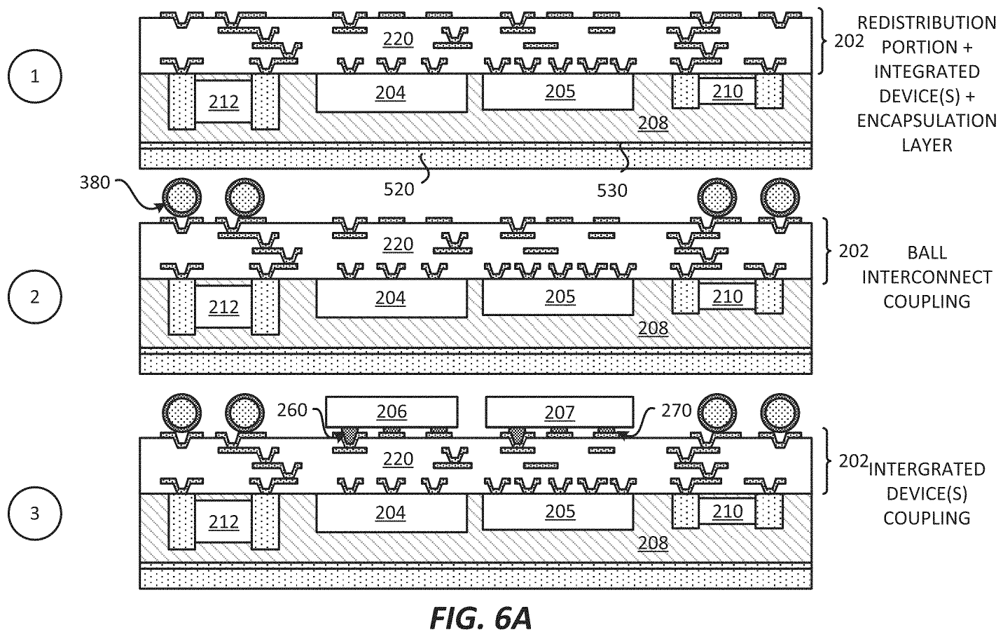

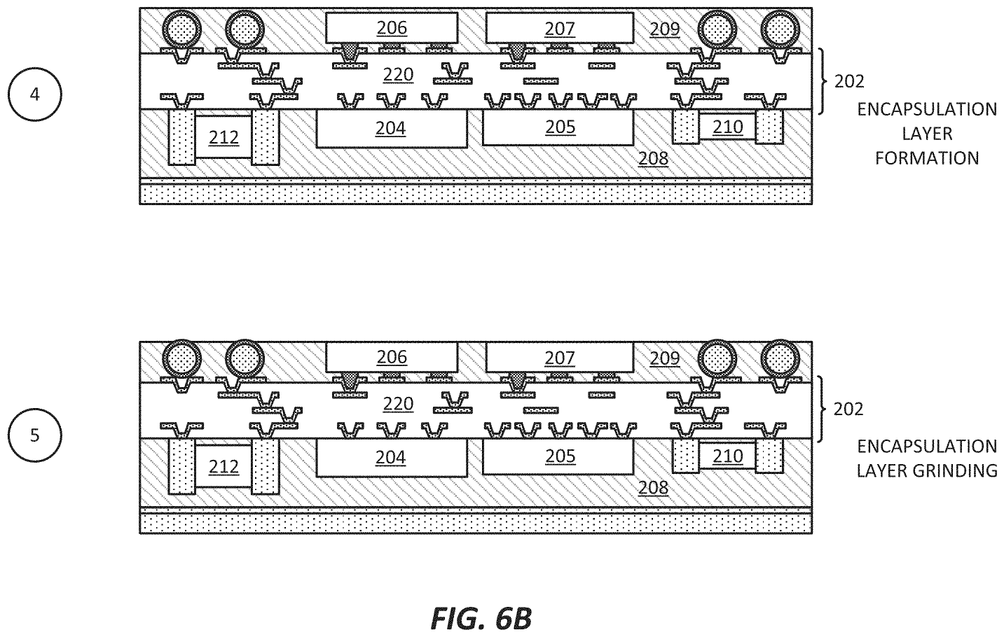

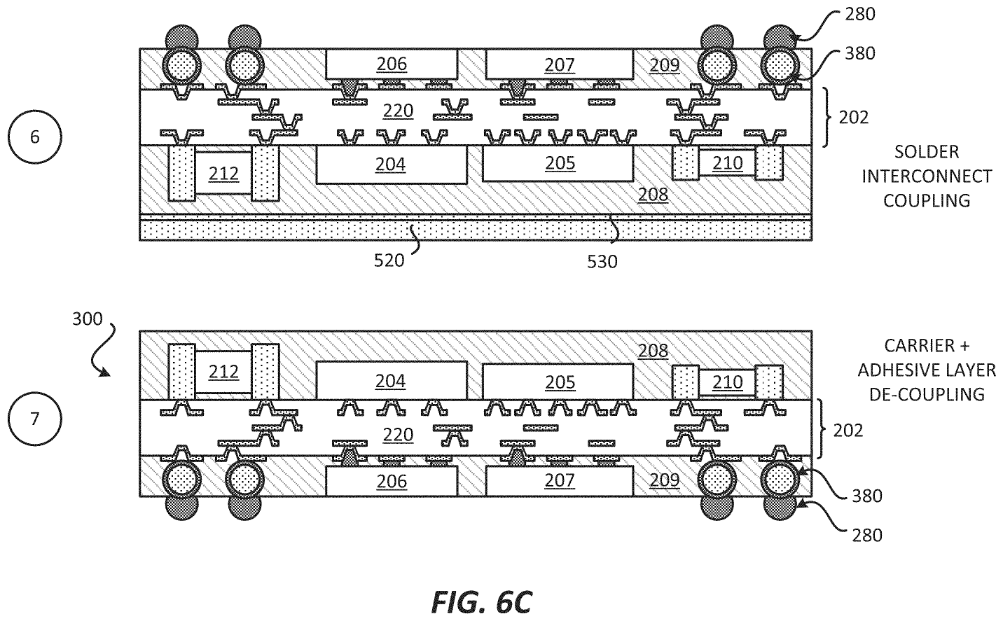

FIGS. 6A-6C illustrate an exemplary sequence for providing or fabricating a package that includes a double-sided redistribution portion. In some implementations, the sequence of FIGS. 6A-6C may be used to provide or fabricate the package 300 of FIG. 3, or any of the packages described in the disclosure.

It should be noted that the sequence of FIGS. 6A-6C may combine one or more stages in order to simplify and/or clarify the sequence for providing or fabricating the package. In some implementations, the order of the processes may be changed or modified. In some implementations, one or more of processes may be replaced or substituted without departing from the spirit of the disclosure. Different implementations may fabricate a package differently.

Stage 1, as shown in FIG. 6A, illustrates a state after a carrier 520 and an adhesive layer 530, the first encapsulation layer 208, the redistribution portion 202, the integrated device 204, the integrated device 205, the passive device 210 and the passive device 212, are provided. Stage 1 of FIG. 6A, may represent or be similar to Stage 12 of FIG. 5D. Thus, the state shown at Stage 1 of FIG. 6A may be achieved using Stages 1-12 of FIGS. 5A-5D.

Stage 2 illustrates a state after the plurality of ball interconnects 380 is coupled to the second surface of the redistribution portion 202. The plurality of ball interconnects 380 may be coupled to the plurality of redistribution interconnects 222 of the redistribution portion 202. The plurality of ball interconnects 380 may include copper balls and solder interconnects. A pick and a place process and a reflow process may be used to couple the plurality of ball interconnects 380 to the redistribution portion 202.

Stage 3 illustrates a state after the integrated device 206 and the integrated device 207 are coupled to a second surface of the redistribution portion 202. In particular, the integrated device 206 is coupled to redistribution interconnects 222 of the redistribution portion 202, through the plurality of solder interconnects 260. The integrated device 206 is coupled to redistribution interconnects 222 of the redistribution portion 202, through the plurality of solder interconnects 260. The integrated device 207 is coupled to redistribution interconnects 222 of the redistribution portion 202, through the plurality of solder interconnects 270.

Stage 4, as shown in FIG. 6B, illustrates a state after the second encapsulation layer 209 is formed over the second surface of the redistribution portion 202, such that the second encapsulation layer 209 at least partially encapsulates the integrated device 206, the integrated device 207, and/or the plurality of ball interconnects 380. The process of forming and/or disposing the second encapsulation layer 209 may include using a compression and transfer molding process, a sheet molding process, or a liquid molding process.

Stage 5 illustrates a state portion of the second encapsulation layer 209 is optionally removed. A grinding process may be used to remove portions of the second encapsulation layer 209. The portions of the second encapsulation layer 209 are removed such that a surface of the second encapsulation layer 209 is co-planar with a surface of the integrated device 206 and/or the integrated device 207.

Stage 6, as shown in FIG. 6C, illustrates a state after the plurality of solder interconnects 280 is coupled to the plurality of ball interconnects 380.

Stage 7 illustrates a state after the adhesive layer 530 and the carrier 520 are decoupled from the first encapsulation layer 208. Stage 7 may include the package 300 that includes the redistribution portion 202, as described in FIG. 3. Stage 7 may illustrate a state after the package 300 has been flipped after the adhesive layer 530 and the carrier 520 are decoupled from the first encapsulation layer 208.

### Exemplary Sequence for Fabricating a Package Comprising a Double-Sided Redistribution Portion

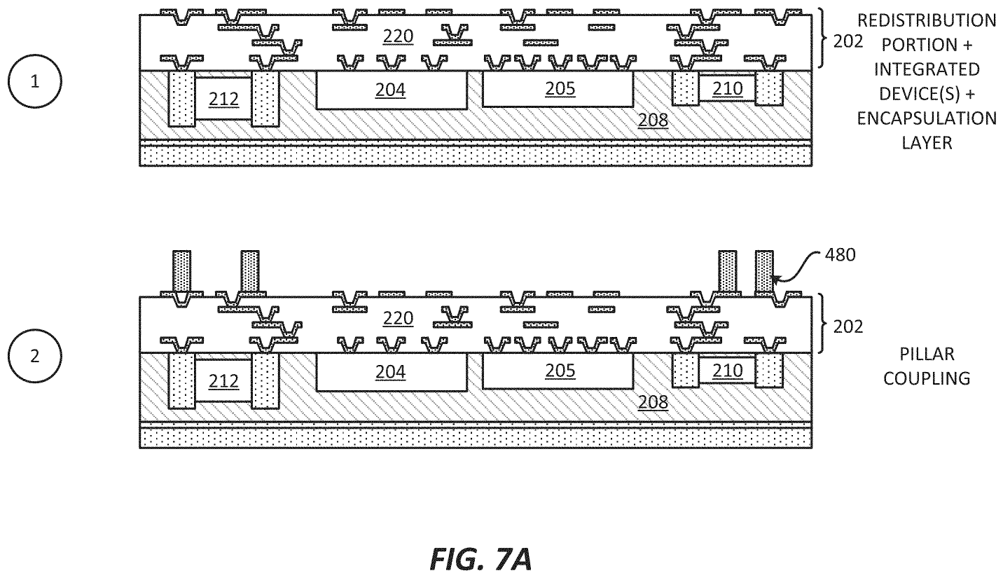

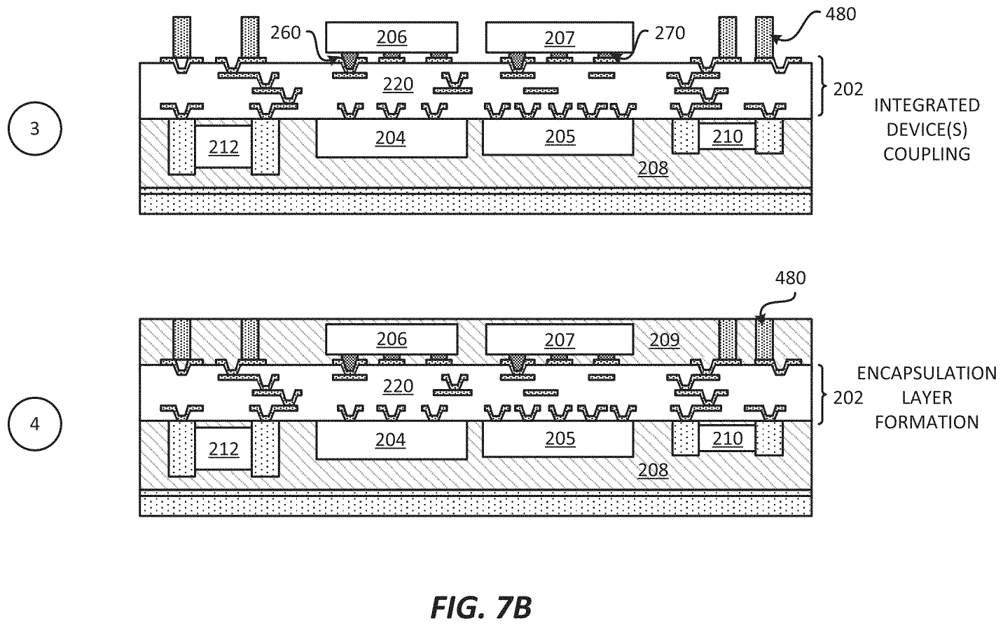

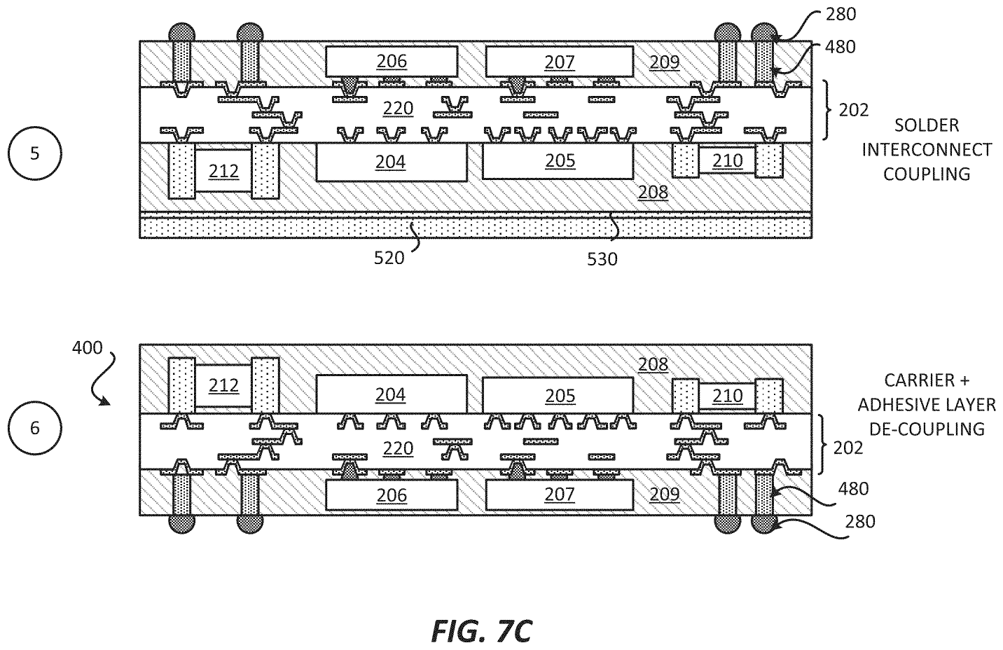

FIGS. 7A-7C illustrate an exemplary sequence for providing or fabricating a package that includes a double-sided redistribution portion. In some implementations, the sequence of FIGS. 7A-7C may be used to provide or fabricate the package 400 of FIG. 4, or any of the packages described in the disclosure.

It should be noted that the sequence of FIGS. 7A-7C may combine one or more stages in order to simplify and/or clarify the sequence for providing or fabricating the package. In some implementations, the order of the processes may be changed or modified. In some implementations, one or more of processes may be replaced or substituted without departing from the spirit of the disclosure. Different implementations may fabricate a package differently.

Stage 1, as shown in FIG. 7A, illustrates a state after a carrier 520 and an adhesive layer 530, the first encapsulation layer 208, the redistribution portion 202, the integrated device 204, the integrated device 205, the passive device 210 and the passive device 212, are provided. Stage 1 of FIG. 7A, may represent or be similar to Stage 12 of FIG. 5D. Thus, the state shown at Stage 1 of FIG. 7A may be achieved using Stages 1-12 of FIGS. 5A-5D.

Stage 2 illustrates a state after the plurality of pillar interconnects 480 is coupled to the second surface of the redistribution portion 202. The plurality of pillar interconnects 480 may be coupled to the plurality of redistribution interconnects 222 of the redistribution portion 202. In some implementations, a deposition process (e.g., plating process, sputtering process) may be used to form the plurality of pillar interconnects 480 over the redistribution portion 202. In some implementations, a pick and a place process may be used to couple the plurality of pillar interconnects 480 to the redistribution portion 202. Solder interconnects may be used to couple the plurality of pillar interconnects 480 to the plurality of redistribution interconnects 222.

Stage 3, as shown in FIG. 7B, illustrates a state after the integrated device 206 and the integrated device 207 are coupled to a second surface of the redistribution portion 202. In particular, the integrated device 206 is coupled to redistribution interconnects 222 of the redistribution portion 202, through the plurality of solder interconnects 260. The integrated device 206 is coupled to redistribution interconnects 222 of the redistribution portion 202, through the plurality of solder interconnects 260. The integrated device 207 is coupled to redistribution interconnects 222 of the redistribution portion 202, through the plurality of solder interconnects 270.

Stage 4 illustrates a state after the second encapsulation layer 209 is formed over the second surface of the redistribution portion 202, such that the second encapsulation layer 209 at least partially encapsulates the integrated device 206, the integrated device 207, and/or the plurality of pillar interconnects 480. The process of forming and/or disposing the second encapsulation layer 209 may include using a compression and transfer molding process, a sheet molding process, or a liquid molding process.

Stage 5, as shown in FIG. 7C, illustrates a state after the plurality of solder interconnects 280 is coupled to the plurality of pillar interconnects 480.

Stage 6 illustrates a state after the adhesive layer 530 and the carrier 520 are decoupled from the first encapsulation layer 208. Stage 6 may include the package 400 that includes the redistribution portion 202, as described in FIG. 4. Stage 6 may illustrate a state after the package 400 has been flipped after the adhesive layer 530 and the carrier 520 are decoupled from the first encapsulation layer 208.

### Exemplary Flow Diagram of a Method for Fabricating a Package Comprising a Double-Sided Redistribution Portion

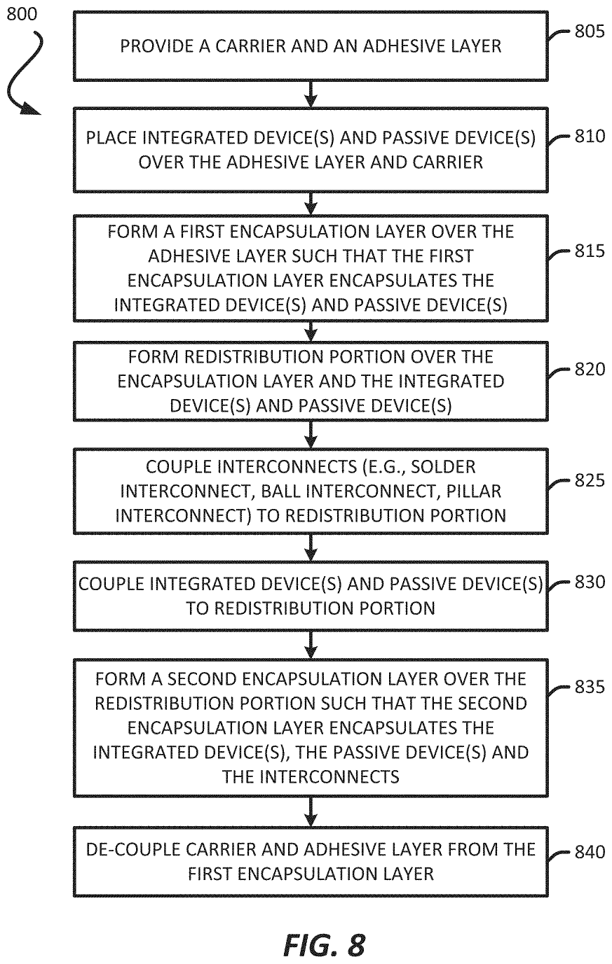

In some implementations, fabricating a package that includes a double-sided redistribution portion includes several processes. FIG. 8 illustrates an exemplary flow diagram of a method 800 for providing or fabricating a package that includes a double-sided redistribution portion. In some implementations, the method 800 of FIG. 8 may be used to provide or fabricate the package 200 of FIG. 2 described in the disclosure. However, the method 800 may be used to provide or fabricate any of the packages (e.g., 300, 400) described in the disclosure.

It should be noted that the sequence of FIG. 8 may combine one or more processes in order to simplify and/or clarify the method for providing or fabricating a package that includes a double-sided redistribution portion. In some implementations, the order of the processes may be changed or modified.

The method provides (at 805) a carrier (e.g., 500) and an adhesive layer (510). The carrier 500 may be a substrate and/or a wafer. The carrier 500 may include glass and/or silicon. The carrier 500 may be a first carrier. The adhesive layer 510 may be disposed (e.g., formed) over the carrier 500. The adhesive layer 510 may be an adhesive film. Stage 1 of FIG. 5A illustrates an example of a carrier and an adhesive layer being provided.

The method places (at 810) integrated device(s) and passive device(s) over the adhesive layer and the carrier. For example, the method may perform a pick and place operation to place the integrated device 204, the integrated device 205, the passive device 210 and the passive device 212 over the adhesive layer 510 and the carrier 500. Different implementations may place different devices and/or different number of devices over the adhesive layer 510 and the carrier 500. Stage 2 of FIG. 5A illustrates an example of integrated devices and passive devices being placed over an adhesive layer and a carrier.

The method forms (at 815) a first encapsulation layer (e.g., 208) over the adhesive layer 510 and the carrier 500, such that the first encapsulation layer 208 at least partially encapsulates the integrated devices and the passive devices. For example, the first encapsulation layer 208 may be formed such that the first encapsulation layer 208 at least partially encapsulates the integrated device 204, the integrated device 205, the passive device 210 and the passive device 212. The process of forming and/or disposing the first encapsulation layer 208 may include using a compression and transfer molding process, a sheet molding process, or a liquid molding process. Stage 3 of FIG. 5A illustrates an example of forming a first encapsulation layer.

The method forms (at 820) a redistribution portion (e.g., 202) over the first encapsulation layer (e.g., 208), the integrated devices and the passive devices. A first surface of the redistribution portion may be formed and/or coupled to first encapsulation layer, the integrated devices and the passive devices. Forming the redistribution portion includes forming at least one dielectric layer (e.g., 220) and a plurality of redistribution interconnects (e.g., 222). Forming the plurality of redistribution interconnects 222 may include forming a seed layer, performing a lithography process, a plating process, a stripping process and/or an etching process. Stages 5-12 of FIGS. 5B-5D may illustrate examples of forming a redistribution portion over the first encapsulation layer, the integrated devices and the passive devices.

The method couples (at 825) interconnects to a second surface of the redistribution portion (e.g., 202). Different implementations may couple different types of interconnects. In some implementations, the method couples (at 825) solder interconnects (e.g., 580, 280) to a second surface of the redistribution portion (e.g., 202). For example, the solder interconnects may be coupled to the redistribution interconnects 222. In some implementations, the method couples (at 825) ball interconnects (e.g., 380) to a second surface of the redistribution portion (e.g., 202). For example, the ball interconnects may be coupled to the redistribution interconnects 222. In some implementations, the method couples (at 825) pillar interconnects (e.g., 480) to a second surface of the redistribution portion (e.g., 202). For example, the pillar interconnects may be coupled to the redistribution interconnects 222. Stage 14 of FIG. 5D, Stage 2 of FIG. 6A, and Stage 2 of FIG. 7A may illustrate examples of coupling interconnects to the second surface of the redistribution portion.

The method couples (at 830) integrated devices and passive devices to the second surface of the redistribution portion (e.g., 202). In some implementations, solder interconnects (e.g., 260, 270) may be used to couple integrated devices (e.g., 206, 207) and/or passive devices to the redistribution interconnects 222 of the redistribution portion 202. Stage 13 of FIG. 5D, Stage 3 of FIG. 6A, and Stage 3 of FIG. 7B may illustrate examples of integrated devices coupled to the second surface of the redistribution portion.

The method forms (at 835) a second encapsulation layer (e.g., 209) over the second surface of the redistribution portion 202, such that the second encapsulation layer at least partially encapsulates the integrated devices (e.g., 206, 207), the interconnects (e.g., 380, 480, 580). The second encapsulation layer may also at least partially encapsulate passive devices. The process of forming and/or disposing the second encapsulation layer 209 may include using a compression and transfer molding process, a sheet molding process, or a liquid molding process. Stage 15 of FIG. 5E, Stage 4 of FIG. 6B and Stage 4 of FIG. 7B may illustrates examples of a second encapsulation layer formed over the redistribution portion.

In some implementations, after the second encapsulation layer is formed, cavities may be formed in the second encapsulation, and/or solder interconnects (e.g., 280) may be provided over the interconnects (e.g., 380, 480, 580).

The method decouples (at 840) the adhesive layer (e.g., 530) and the carrier (e.g., 520) from the first encapsulation layer (e.g., 208), leaving the package (e.g., 200, 300, 400) that includes the redistribution portion 202. Stage 18 of FIG. 5F, Stage 7 of FIG. 6C, and Stage 6 of FIG. 7C may illustrate examples of decoupling of the adhesive layer and the carrier.

### Exemplary Electronic Devices

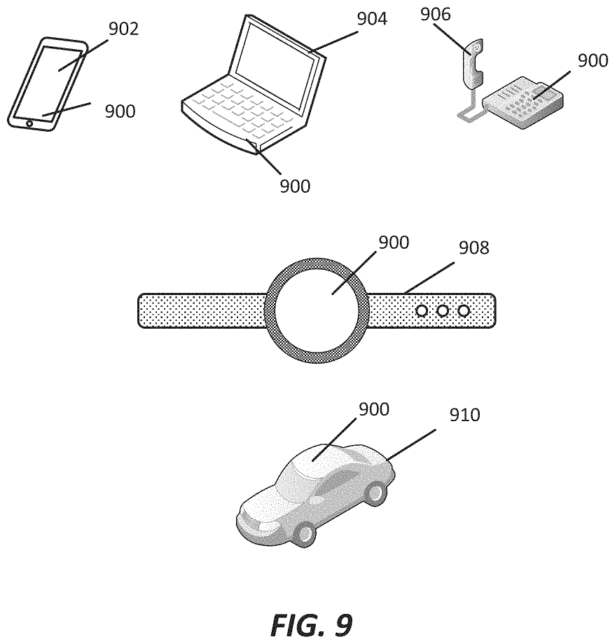

FIG. 9 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 902, a laptop computer device 904, a fixed location terminal device 906, a wearable device 908, or automotive vehicle 910 may include a device 900 as described herein. The device 900 may be, for example, any of the devices and/or integrated circuit (IC) packages described herein. The devices 902, 904, 906 and 908 and the vehicle 910 illustrated in FIG. 9 are merely exemplary. Other electronic devices may also feature the device 900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 2-4, 5A-5F, 6A-6C, 7A-7C, and/or 8-9 may be rearranged and/or combined into a single component, process, feature or function or embodied in several components, processes, or functions. Additional elements, components, processes, and/or functions may also be added without departing from the disclosure. It should also be noted FIGS. 2-4, 5A-5F, 6A-6C, 7A-7C, and/or 8-9 and its corresponding description in the present disclosure is not limited to dies and/or ICs. In some implementations, FIGS. 2-4, 5A-5F, 6A-6C, 7A-7C, and/or 8-9 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. The term “encapsulating” means that the object may partially encapsulate or completely encapsulate another object. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a redistribution metal layer, and/or an under bump metallization (UBM) layer. An interconnect may include one or more metal components (e.g., seed layer+metal layer). In some implementations, an interconnect is an electrically conductive material that may be configured to provide an electrical path for a signal (e.g., a data signal, ground or power). An interconnect may be part of a circuit. An interconnect may include more than one element or component. An interconnect may be defined by one or more interconnects. Different implementations may use similar or different processes to form the interconnects. In some implementations, a chemical vapor deposition (CVD) process and/or a physical vapor deposition (PVD) process for forming the interconnects. For example, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first integrated device;
a first encapsulation layer encapsulating the first integrated device;
a redistribution portion comprising a plurality of redistribution interconnects,
wherein the redistribution portion comprises a first surface and a second surface, and
wherein the first integrated device and the first encapsulation layer are coupled to the first surface of the redistribution portion;
a second integrated device coupled to the second surface of the redistribution portion; and
a second encapsulation layer coupled to the second surface of the redistribution portion such that the second encapsulation layer encapsulates the second integrated device.

2. The package of claim 1, further comprising a plurality of solder interconnects coupled to the second surface of the redistribution portion, wherein the plurality of solder interconnects is at least partially encapsulated by the second encapsulation layer.

3. The package of claim 1, further comprising a plurality of ball interconnects coupled to the second surface of the redistribution portion, wherein the plurality of ball interconnects is at least partially encapsulated by the second encapsulation layer.

4. The package of claim 3, wherein the plurality of ball interconnects comprises copper balls.

5. The package of claim 1, further comprising a plurality of pillar interconnects coupled to the second surface of the redistribution portion, wherein the plurality of pillars interconnects is at least partially encapsulated by the second encapsulation layer.

6. The package of claim 1, wherein the first integrated device is coupled to a redistribution interconnect from the plurality of redistribution interconnects.

7. The package of claim 1,
wherein the first integrated device is coupled to a first redistribution interconnect from the plurality of redistribution interconnects such that the coupling between the first integrated device and the first redistribution interconnect is free of solder interconnect, and
wherein the second integrated device is coupled to a second redistribution interconnect from the plurality of redistribution interconnects through a solder interconnect.

8. The package of claim 1, further comprising a first passive device coupled to the first surface of the redistribution portion, wherein the first passive device is encapsulated by the first encapsulation layer.

9. The package of claim 1, wherein each redistribution interconnects from the plurality of redistribution interconnects comprises a thickness of approximately 5-10 micrometers (μm).

10. The package of claim 1, wherein the package is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

11. An apparatus comprising:
a first integrated device;
first means for encapsulation configured for encapsulating the first integrated device;
a redistribution portion comprising a plurality of redistribution interconnects,
wherein the redistribution portion comprises a first surface and a second surface, and
wherein the first integrated device and the first means for encapsulation are coupled to the first surface of the redistribution portion;
a second integrated device coupled to the second surface of the redistribution portion; and
second means for encapsulation coupled to the second surface of the redistribution portion, the second means for encapsulation configured for encapsulating the second integrated device.

12. The apparatus of claim 11, further comprising a plurality of solder interconnects coupled to the second surface of the redistribution portion, wherein the plurality of solder interconnects is at least partially encapsulated by the second means for encapsulation.

13. The apparatus of claim 11, further comprising a plurality of ball interconnects coupled to the second surface of the redistribution portion, wherein the plurality of ball interconnects is at least partially encapsulated by the second means for encapsulation.

14. The apparatus of claim 13, wherein the plurality of ball interconnects comprises copper balls.

15. The apparatus of claim 11, further comprising a plurality of pillar interconnects coupled to the second surface of the redistribution portion, wherein the plurality of pillars interconnects is at least partially encapsulated by the second means for encapsulation.

16. The apparatus of claim 11, wherein the first integrated device is coupled to a redistribution interconnect from the plurality of redistribution interconnects.

17. The apparatus of claim 11,
wherein the first integrated device is coupled to a first redistribution interconnect from the plurality of redistribution interconnects such that the coupling between the first integrated device and the first redistribution interconnect is free of solder interconnect, and
wherein the second integrated device is coupled to a second redistribution interconnect from the plurality of redistribution interconnects through a solder interconnect.

18. The apparatus of claim 11, wherein each redistribution interconnects from the plurality of redistribution interconnects comprises a thickness of approximately 5-10 micrometers (μm).

19. The apparatus of claim 11, wherein at least one redistribution interconnect from the plurality of redistribution interconnects comprises a U-shape interconnect or V-shape interconnect.

20. The apparatus of claim 11, wherein the apparatus is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

21. A method for fabricating a package, comprising:
providing a first integrated device;
forming a first encapsulation layer over the first integrated device;
forming a redistribution portion over the first integrated device and the first encapsulation layer, wherein forming the redistribution portion comprises forming a plurality of redistribution interconnects;
coupling a second integrated device to a second surface of the redistribution portion; and
forming a second encapsulation layer over the second surface of the redistribution portion such that the second encapsulation layer encapsulates the second integrated device.

22. The method of claim 21, further comprising coupling a plurality of solder interconnects to the second surface of the redistribution portion, wherein the plurality of solder interconnects is at least partially encapsulated by the second means for encapsulation.

23. The method of claim 21, further comprising a plurality of ball interconnects coupled to the second surface of the redistribution portion, wherein the plurality of ball interconnects is at least partially encapsulated by the second means for encapsulation.

24. The method of claim 23, wherein the plurality of ball interconnects comprises copper balls.

25. The method of claim 21, further comprising a plurality of pillar interconnects coupled to the second surface of the redistribution portion, wherein the plurality of pillars interconnects is at least partially encapsulated by the second means for encapsulation.
